(19) United States
(12) Patent Application Publication
(10) Pub. No.: US 2025/0107443 A1
(43) Pub. Date: Mar. 27, 2025

(54) EFFICIENT HEAT ENERGY UTILIZATION SYSTEM AND METHOD FOR ELECTRONIC AND ELECTRICAL DEVICES

(71) Applicant: Shashank Kamaljit Bhatia, New Delhi (IN)

(72) Inventor: Shashank Kamaljit Bhatia, New Delhi (IN)

(21) Appl. No.: 18/674,960

(22) Filed: May 27, 2024

(30) Foreign Application Priority Data
Sep. 8, 2023 (IN) 202311060414

(51) Int. Cl. H10N 10/13; F24F 5/00

(52) U.S. Cl. CPC H10N 10/13; F24F 5/0042

(57) ABSTRACT

Embodiments disclosed include systems and methods for utilizing heat generated by electronic, electrical, mechanical, and electromechanical devices. Embodiments disclosed enable the collection of heat generated from one or more heat-generating components of a device. The collected heat is converted into electrical energy through a Thermoelectric Generator (TEG) integrated within a heat exchanger to obtain auxiliary power. The heat energy is converted to electrical energy by exposing one side of the heat exchanger (hot side) to the heat-generating component of the device, i.e., a high-temperature heat reservoir and an opposite side of the heat exchanger (cold side) to a low-temperature heat reservoir. The main power is received from a power supply system. The main power and auxiliary power are aggregated and supplied to the device for its operation, thereby optimizing power generation and heat management for the device.

### FIELD OF THE INVENTION

The present invention relates to thermo-electric power generation, and particularly to generate power using waste heat produced by electrical, mechanical, electro-mechanical, and electronic devices

### BACKGROUND OF THE INVENTION

Background description includes information that may be useful in understanding the present invention. It is not an admission that any of the information provided herein is prior art or relevant to the presently claimed invention or that any publication specifically or implicitly referenced is prior art.

Electrical, electronic, mechanical, and electro-mechanical devices produce heat while they operate. With increasing usage of such devices, most of the area in the world has recorded a significant rise in surface air temperature, land surface temperature, and relative humidity (heat index). Usage of such devices also results in maximum variations in temperatures in different areas.

In the realm of electronic and electrical devices, energy efficiency and sustainable power utilization are of paramount importance. Conventional systems typically rely on dissipating excess heat generated during device operation into the environment, leading to significant energy wastage and operational inefficiencies. While some methods using heat sinks and fans have been employed to mitigate overheating, they fail to harness the wasted heat effectively, and often lead to excessive power consumption.

Conventional techniques for utilizing heat energy generated by electrical, electronic, mechanical, and electro-mechanical devices have typically yielded little in mitigating heat pollution. This is because the common approach has been to dissipate the heat into the environment through heat sinks or cooling systems rather than effectively capturing and utilizing it. This results in wasted energy and a missed opportunity to convert the heat into usable electrical power.

Another conventional method involves using separate systems for power generation and heat management. Power generation systems, such as thermoelectric generators (TEGs), have been used to convert heat energy into electrical energy. However, these systems often lack integration with the device's power management system, leading to suboptimal power utilization and inefficient overall operation.

Significant rise in temperature results in the drastic rise in the number of heat hotspots in the world. Loss in green cover, seasonal loss of vegetation and urban activities are believed to be among the reasons behind the rise in temperature. A report stated that air surface temperature was currently 1.77 degrees Celsius more than the 1981-2010 baseline, while the land surface temperature was 1.95 degrees Celsius more. The heat index is up by 1.64 degrees Celsius compared with the 2010-19 baseline.

Additionally, cumulative power consumption in operation of electrical, electronic, mechanical, and electro-mechanical devices has drastically increased in the last few years. Now-a-days, with increase in production and launches of new devices, re-usability of energy remains a challenge, especially at the end consumer level.

Conventional methods often fail to capture and utilize heat energy generated by electrical, electronic, mechanical, and electro-mechanical devices. This leads to energy waste and reduces overall efficiency. Further, existing power generation systems are often not integrated with the device's power management system. This results in suboptimal power utilization and inefficiencies in overall operation. Furthermore conventional systems have limited applicability and are not designed to efficiently harness heat energy from specific devices like air conditioners, where significant heat is generated.

There is a clear need for an integrated system and method that efficiently captures and utilizes heat energy from electrical, electronic, mechanical, and electro-mechanical devices and effectively captures and converts heat energy into electrical energy, reducing energy waste and maximizing overall efficiency. There is a further need for systems and methods that can re-use heat energy converted to electrical energy, in real-time, and seamlessly integrate with the device's power management system, ensuring optimal power utilization and efficient operation.

Thus, there is a need for re-utilization of heat generated by electrical and electronic devices which may overcome above-mentioned shortcomings of heat dissipated in the environment.

### SUMMARY OF THE INVENTION

The present invention relates to a method and system for the utilization of heat generated from electronic or electrical devices. The objective of the invention is to overcome the limitations of conventional techniques by efficiently capturing and converting heat energy into electrical power, integrating it with the device's power management system, and optimizing power generation and heat management.

According to an aspect of the present disclosure, a method for utilization of heat generated from an electronic or electrical device is disclosed. The method comprises collecting a portion of heat generated from one or more heat generating components of the device. The collected heat from the device is converted into electrical energy to obtain auxiliary power. The heat energy is converted to electrical energy by exposing the portion of heat to a high-temperature heat reservoir and a heat sink to a low-temperature heat reservoir. The main power is received from a power supply system. A load requirement is maintained for operation of the device. The main power and the auxiliary power are aggregated based on a load requirement and the obtained portion of heat. The aggregated power is provided to the device for its operation, thereby optimizing power generation and reducing the quantum of heat dissipated into the environment.

According to an embodiment, the system comprises a heat collecting component, a thermo-electric generator (TEG), and a power management module. The heat collecting component collects the heat generated by the device, and the TEG converts it into electrical energy. The power management module receives both main power from a power supply system and auxiliary power generated by the TEG. The power management module is configured to aggregate power from the power supply system and the TEG such that the power drawn from the power supply is the total load requirement minus the auxiliary power generated by the TEG. Thus the aggregated power, i.e. auxiliary power generated added to the power drawn from the power supply is then provided to the device for its operation, optimizing power generation and heat management.

The objective of the present invention is a thermo-electric generator (TEG) integrated into a heat exchanger. This TEG effectively converts excess heat energy into electrical power by leveraging the temperature differential between a hot side and a cold side within the heat exchanger.

In an aspect, heat is collected via a heat sink of the device.

In an aspect, the heat energy is converted into the electrical energy through a series connection of p-type and n-type semiconductors of a thermo-electric power generator.

In an aspect, a ratio between the main power and the auxiliary power in the aggregated power is based on the load requirement and the quantum of auxiliary power generated by the TEG

In an aspect, the device is further connected to a secondary power source for proper operation in case of system failure. In an aspect, the secondary power source comprises a chargeable battery bank connected to the auxiliary power source.

In an aspect, auxiliary power generated is supplied back to the grid.

In an aspect, the device ensures improved energy efficiency by capturing and utilizing heat energy that would otherwise be dissipated into the environment, exacerbating heat pollution. The integration of the TEG with the device's power management system allows for optimal power utilization and efficient operation. The system is adaptable to different devices, particularly air-conditioners and heat exchange systems, which generate significant amounts of heat. Additionally, the invention contributes to sustainability efforts by harnessing wasted heat energy, reducing reliance on conventional power sources, but more importantly, drastically reducing heat dissipated into the environment by virtue of converting heat energy into electrical energy.

In an aspect, the present invention provides an innovative method and system for the utilization of heat energy from electrical, electronic, mechanical, and electro-mechanical devices. By efficiently capturing and converting heat into electrical power, integrating it with the device's power management system, and optimizing power generation and heat management, the invention overcomes the limitations of conventional techniques and offers significant advantages in energy efficiency and sustainability

According to an embodiment, a system for conversion of heat energy generated by and captured from an electrical, electronic, mechanical, or electromechanical device, to electrical energy, is disclosed. The system comprises collecting a portion of heat generated from one or more heat generating components of the device. Heat energy of the portion of heat is converted into electrical energy to obtain auxiliary power. The heat energy is converted to the electrical energy by exposing the portion of heat to a high-temperature heat reservoir and a heat sink to a low-temperature heat reservoir. The main power is received from a power supply system. The device load requirement is fulfilled by aggregating main power and the generated auxiliary power from the heat generated by the electrical or electronic device. The aggregated power is provided to the device for its operation, thereby optimizing power generation and heat management for the device.

In an aspect, the electrical device is an air-conditioner.

In an aspect, the air-conditioner comprises a heat sink configured to extract the heat produced by the device through a coolant flowing through a condenser. The heat sink has hot side or heat absorber coupled with a conduit of the condenser for collecting the heat and a cold side or heat dissipator such that the temperature differential between the hot side and the cold side results in the generation of electrical energy in the Seebeck effect, which is then supplied back to the load as auxiliary power.

In an aspect, the TEG comprises a heat absorbing plate in thermal communication with the heat exchanger, and wherein the TEG comprises a heat dissipater in thermal communication with a low temperature environment.

In an aspect, the TEG comprises a plurality of thermoelectric converters present between the heat absorbing plate and the heat dissipater.

In an aspect, the system comprises a battery operably connected to the power management module.

### BRIEF DESCRIPTION OF DRAWINGS

To further clarify the advantages and features of the present disclosure, a more particular description of the disclosure will be rendered by reference to specific embodiments thereof, which is illustrated in the appended drawings. It is appreciated that these drawings depict only typical embodiments of the disclosure and are therefore not to be considered limiting of its scope. The disclosure will be described and explained with additional specificity and detail with the accompanying drawings.

The subject matter that is regarded as the invention is particularly pointed 10 out and distinctly claimed in the claims at the conclusion of the specification. The foregoing and other aspects, features, and advantages of the invention are apparent from the following detailed description taken in conjunction with the accompanying drawings in which.

FIG. 1 illustrates a block diagram of an overall system for re-utilizing heat energy generated from an electronic device, in accordance with an embodiment of the present invention;

FIG. 2 illustrates a block diagram of a system for generating electric 20 power from heat energy dissipated by an electronic device, in accordance with an embodiment of the present invention;

FIG. 3 illustrates a block diagram of condenser and evaporator of an air conditioner, in accordance with an embodiment of the present invention:

FIG. 4 illustrates a block diagram of internal components of the air conditioner, in accordance with an embodiment of the present invention:

FIG. 5 illustrates a block diagram of a system for utilization of auxiliary 30 power, in accordance with an embodiment of the present invention;

FIG. 6 illustrates positioning of the thermoelectric device, in accordance with an embodiment of the present invention:

FIG. 7 illustrates connection between the thermoelectric device, in accordance with an embodiment of the present invention; and

FIG. 8 illustrates a block diagram of the thermoelectric device, in accordance with an embodiment of the present invention.

Further, skilled artisans will appreciate that elements in the drawings are illustrated for simplicity and may not have necessarily been drawn to scale. Furthermore, in terms of the construction of the device, one or more components of the device may have been represented in the drawings by conventional symbols, and the drawings may show only those specific details that are pertinent to understanding the embodiments of the present invention so as not to obscure the drawings with details that will be readily apparent to those of ordinary skill in the art having benefit of the description herein.

### DETAILED DESCRIPTION OF THE INVENTION

For the purpose of promoting an understanding of the principles of the invention, reference will now be made to the embodiment illustrated in the drawings, and specific language will be used to describe the same. It will nevertheless be understood that no limitation of the scope of the invention is thereby intended. Such alterations and further modifications in the illustrated system, and such further applications of the principles of the invention as illustrated therein would be contemplated as would normally occur to one skilled in the art to which the invention relates. Unless otherwise defined, all technical and scientific terms used herein have the same meaning as commonly understood by one of ordinary skill in the art. The system, methods, and examples provided herein are illustrative only and are not intended to be limiting.

The present invention introduces a novel method and system for effectively utilizing heat generated by electrical, electronic, mechanical, and electro mechanical devices. The system includes several key components that work together to capture, convert, and manage the heat energy. A heat collecting/absorbing/concentrating component is responsible for gathering the heat generated by the device's heat generating components, such as a heat sink. This collected heat is then transferred to a Thermoelectric Generator (TEG) through thermal coupling. Alternatively the heat sink is comprised in a first side of the Thermoelectric Generator (TEG) i.e. the hot side and operatively coupled to a second side of the TEG, i.e. the cold side. The TEG plays a crucial role in converting the heat energy into electrical energy, employing a series connection of p-type and n-type semiconductors between the hot side and the cold side according to an embodiment. This conversion process occurs by exposing a first side of the TEG to the collected heat and a second side which essentially is at a lower temperature wherein the temperature differential creates a voltage, which is utilized in an auxiliary power supply in a return path or closed loop to supplement power from a primary power source.

To optimize power generation and heat management, the present invention incorporates a power management module/system as a vital component of the system. This module acts as a control center, receiving primary power from a primary power supply system/source and auxiliary power generated by the TEG. By monitoring the device's load requirement, the power management module can aggregate the primary power and the auxiliary power in a manner that fulfils the load requirement while taking advantage of the heat generated by the electrical, electronic, mechanical, or electro-mechanical device/appliance. The amount of the primary power in the aggregated power is determined based on the load requirement and the amount of auxiliary power available. This intelligent power management ensures efficient utilization of all available power sources.

The system designed based on the present invention is versatile and can be applied to various electrical, electronic, mechanical, or electro-mechanical devices. For instance, in the case of an air-conditioner, the system integrates seamlessly with the device's existing components. A heat sink, which extracts heat produced by the air-conditioner, is coupled with a conduit of the condenser to collect the generated heat. This collected heat is then utilized by the TEG to generate auxiliary power. Moreover, to ensure uninterrupted operation, the system can be connected to a battery that acts as a backup power source in the event of a system failure. With its adaptability and energy-efficient design, the present invention offers significant advancements in power generation and heat management for electronic and electrical devices.

According to an embodiment of the present invention, a method is provided for efficiently utilizing heat generated from an electrical, electronic, mechanical, or electro-mechanical device. The method involves collecting the heat generated by one or more heat generating components of the device. According to an embodiment the heat is collected by thermally coupling a heat exchanger to the heat generating component of the device. Preferably, the heat exchanger further comprises a thermoelectric generator (TEG) wherein the heat exchanger further comprises a hot side or heat absorber/concentrator thermally coupled to the heat generating component of the device and a cold side or heat dissipator, thus creating a temperature differential to generate power from the heat of the electrical/electronic device.

The method further includes receiving power from a primary power supply/source and monitoring the load requirement for the device's operation. The power from the primary power supply/source and the auxiliary power generated are aggregated to align with the load requirement and thus minimize power consumption from the primary power source, even while minimizing the quantum of heat dissipated. By implementing this method, the utilization of heat energy is maximized and dissipation of heat is minimized, leading to improved energy efficiency, cost savings, and reduced environmental impact.

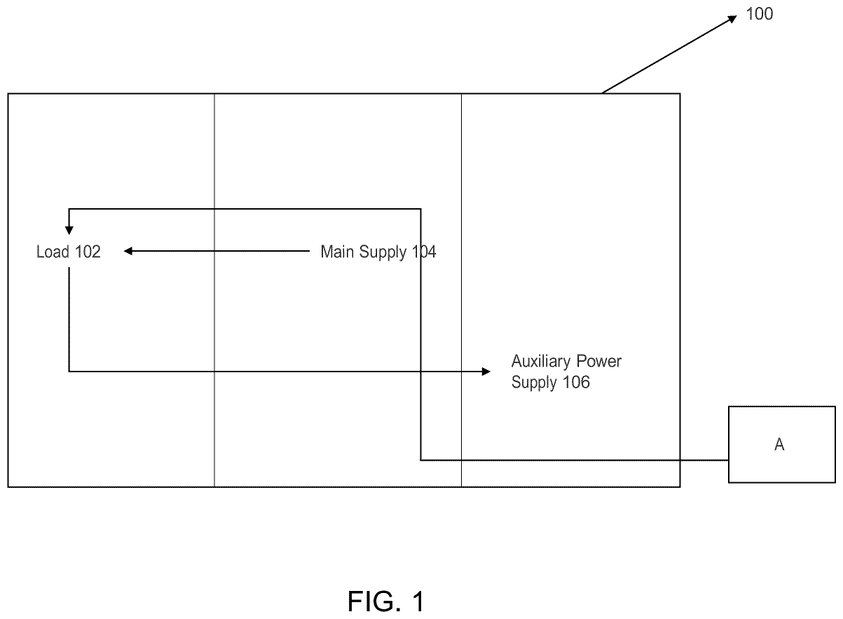

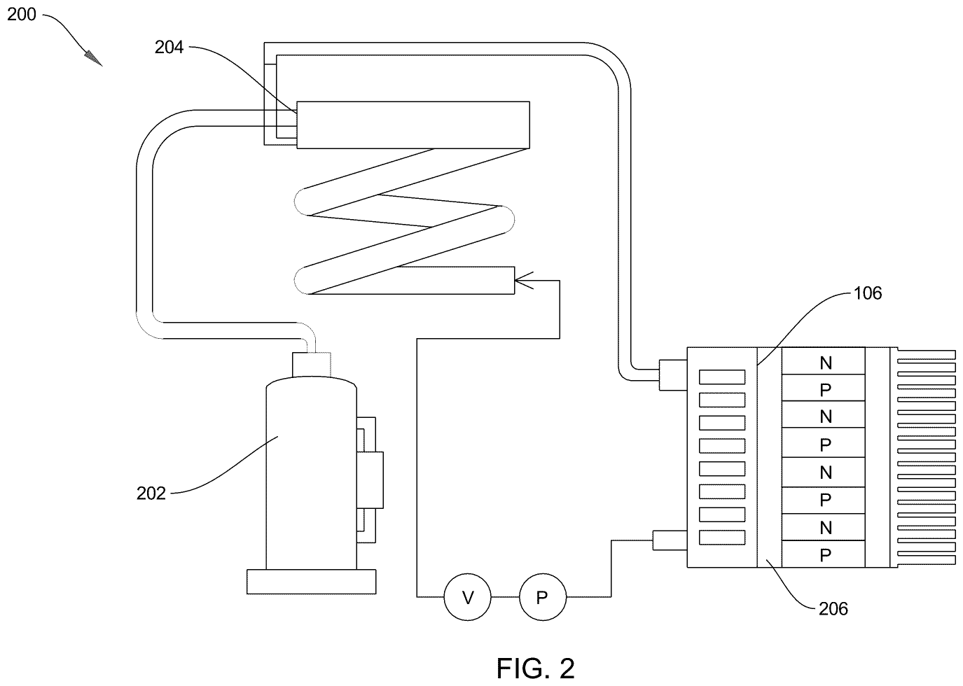

FIG. 1 illustrates a block diagram of an overall system 100 for re-utilizing heat energy generated from an electronic device, in accordance with an embodiment of the present invention. As illustrated in FIG. 1, a load 102 may be connected to a main supply 104 for its operation. In one embodiment, the load 102 may be an Air Conditioner (AC). The load 102 may generate heat energy during usage. Heat energy of the generated heat may captured to be converted into electrical energy. The electrical energy may be provided back to the load 102 as an auxiliary power supply 106. The auxiliary power supply 106 may act as an additional power source to provide power to the load 102. Generation of the electrical energy from the heat energy generated by the electronic device is described in detail successively using FIG. 2.

As according to the present invention, the system 100 ensures that the heat energy produced by the electronic device, such as an air-conditioner, is not dissipated, but rather is effectively transformed into useful electrical power. By harnessing and re-utilizing this heat energy, the system optimizes energy efficiency and reduces consumption of power from the primary power supply. The auxiliary power supply 106 serves as a supplementary source, providing additional power to support the operation of the load 102, thereby enhancing overall performance and functionality.

As according to an embodiment of the present invention, the system 100 enables the efficient utilization of heat energy generated by an electronic device, such as an air-conditioner, by converting it into electrical energy. This converted electrical power is then supplied back to the device as an auxiliary power source, supplementing the primary power supply. The system thus optimizes power generation, minimizes heat dissipation, enhances energy efficiency, and improves the overall performance and operation of the electronic device.

As according to an embodiment of the present invention, the Electronic or Electrical Device or Load (102) represents the device generating heat, such as an air conditioner, compressor, or any other electrical or electronic equipment that produces surplus heat during its operation.

As according to an embodiment of the present invention, the heat Exchanger or main supply (104) serves as the primary component for collecting and transferring heat away from the electronic or electrical device (102). In traditional systems, this component may simply dissipate the heat into the environment, leading to energy wastage and increased operating costs.

As according to an embodiment of the present invention, the thermo-Electric Generator (TEG) or auxiliary power supply (106), wherein 106 is a solid-state semiconductor device placed within the heat exchanger or main supply (104). The TEG operates based on the Seebeck effect, which utilizes temperature differences between the hot side and cold side to generate electrical power. In this context, the hot side is thermally coupled to the heat exchanger or main supply (104), capturing the excess heat, while the cold side is positioned to dissipate heat to a lower-temperature environment.

FIG. 2 illustrates a block diagram of a system 200 for generating electric power from heat energy dissipated by an electronic device, in accordance with an embodiment of the present invention. The electronic device may comprise a heat generating component 202 that generates heat while the electronic device is in operation. In one embodiment, the electronic device may be an air-conditioner. The air-conditioner may comprise a compressor having an inlet valve and an outlet valve. The air-conditioner may further comprise an evaporator having an outlet valve operatively coupled to the compressor's inlet valve. The air-conditioner may comprise a condenser 204 having a refrigerant input line operatively coupled to a compressor's outlet valve and a refrigerant output line operatively coupled to an inlet expansion valve comprised in the evaporator enabling a refrigerant to go from a liquid state at a first temperature to a gaseous state at a second temperature the first temperature being higher than the second temperature.

As according to an embodiment of the present invention, the heat Generating Component (202) represents the specific component within the electronic or electrical device (102) that generates heat during operation. It could be a compressor, a condenser, or any heat-emitting element.

As according to an embodiment of the present invention, the heat Exchanger or condenser (204) is similar to the heat exchanger in FIG. 1, this component collects and transfers excess heat generated by the heat generating component (202), wherein heat exchanger (204), includes a heat-absorbing plate (206) and a heat dissipator.

The condenser 204 may comprise a first conduit operatively coupled to the refrigerant input line at one end thereof and operatively coupled to the refrigerant output line at an opposite end thereof for carrying the refrigerant there between. The system 200 may further comprise a second conduit extending there through the first conduit for carrying a coolant there through. Heat from the refrigerant in the first conduit is transferred to the coolant within the second conduit. The system 200 may further comprise a coolant pump configured for displacing the coolant and operatively coupled to the second conduit and further thermally coupled to a heat sink comprised in a thermoelectric device 206, such as Thermoelectric Generator (TEG). The thermoelectric device 206 may comprise a cold side opposite to the heat sink and is configured to convert the captured heat into auxiliary power.

As according to an embodiment of the present invention, the system 200 is configured to harness heat energy generated by an electronic device, particularly an air-conditioner according to an example embodiment. According to an example embodiment, the electrical device is an air-conditioner and comprises a condenser 204 for condensing refrigerant and facilitating the transfer of heat to a coolant through a first and second conduit arrangement. A coolant pump drives the coolant flow, while a thermoelectric device 206, with a cold side and heat sink, and effectively converts the captured heat into auxiliary power. By employing this configuration, the system optimizes the utilization of heat energy, resulting in the generation of additional electrical power that can be utilized to enhance the overall efficiency and functionality of the electronic device.

As according to an embodiment of the present invention, FIG. 2 illustrates heat exchanger (204) and the TEG, strategically placed within the heat exchanger to maximize heat capture and conversion into electrical energy. The heat-absorbing plate (206) serves as an efficient heat source, and the heat dissipator maintains a lower temperature, creating a temperature gradient across the TEG for generating electrical power

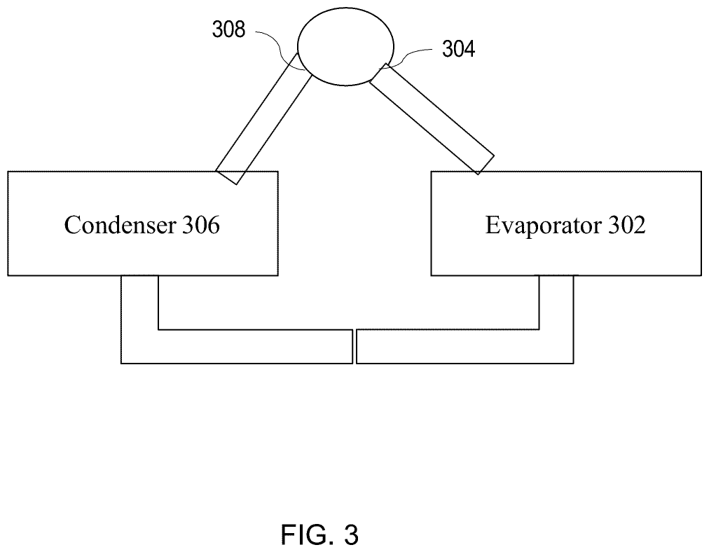

FIG. 3 illustrates a block diagram of condenser and evaporator of an air conditioner, in accordance with an embodiment of the present invention. The air conditioner may comprise an evaporator 302 having an outlet valve operatively coupled to the compressor's inlet valve 304. The air-conditioner may further comprise a condenser 306 having a refrigerant input line operatively coupled to a compressor's outlet valve 308 and a refrigerant output line operatively coupled to an inlet valve comprised in the evaporator, wherein the inlet valve comprised in the evaporator includes an expansion valve which causes the refrigerant to expand, releasing heat as it goes from a liquid state at a first temperature to a gaseous state at a second temperature the first temperature being higher than the second temperature

As according to an embodiment of the present invention, the evaporator (302) is part of the air-conditioning system and configured for cooling the indoor air, wherein the evaporator comprises evaporator coils that play a key role in the cooling process. These evaporator coils allow the refrigerant, typically in a liquid state, to expand and change into a gaseous state as it passes through the expansion valve which transition causes a significant drop in temperature, creating a cold surface within the evaporator.

As according to an embodiment of the present invention, the Condenser (306) is a located in the outdoor unit of the air conditioner, wherein the function is to convert the refrigerant back from a gaseous state to a liquid state. As the refrigerant condenses, it releases heat, which is dissipated into the environment. The condenser often comprises condenser coils that facilitate this heat exchange.

As according to another embodiment, FIG. 2 demonstrates the flow of refrigerant within the air-conditioning system. After passing through the evaporator and changing to a gaseous state, the refrigerant moves out of the evaporator through an outlet valve. It then enters the compressor via a compressor inlet valve. The compressor pressurizes the gaseous refrigerant, increasing its temperature. The high-temperature, high-pressure gas is then directed into the condenser.

As according to the present invention depicted in FIG. 3, the air conditioning system comprises an evaporator 302 and a condenser 306 that work together to achieve the desired cooling effect. The evaporator 302 comprises evaporator coils that enable converting the refrigerant from a liquid state to a gaseous state. For the completion of the process, the refrigerant has to move from the expansion valve to the coils of the evaporator 302. Due to the movement, the refrigerant pressure decreases and the expansion valve causes a change from the liquid state into a gaseous state.

The evaporator coils enable heat transfer, and as a result, a cold surface is created. The blower attached to the air conditioner moves the air and also creates cool conditioned air which decreases the temperature inside a confined space.

The gaseous refrigerant is then passed through the outlet valve of the evaporator and into the compressor through a compressor inlet valve. From the compressor, the refrigerant is pushed into the condenser, where it undergoes condensation, releasing heat as it is converted to a liquid state. This liquid refrigerant is then sent back to the evaporator, and the cycle continues. The condenser 306 may comprise condenser coils placed inside the outdoor unit of the air conditioner. The condenser plays a vital role in converting the refrigerant from a gaseous to a liquid state, while the evaporator facilitates the absorption of heat and the subsequent cooling of the surrounding air. Together, these components enable the air-conditioner to provide a comfortable and pleasant indoor environment.

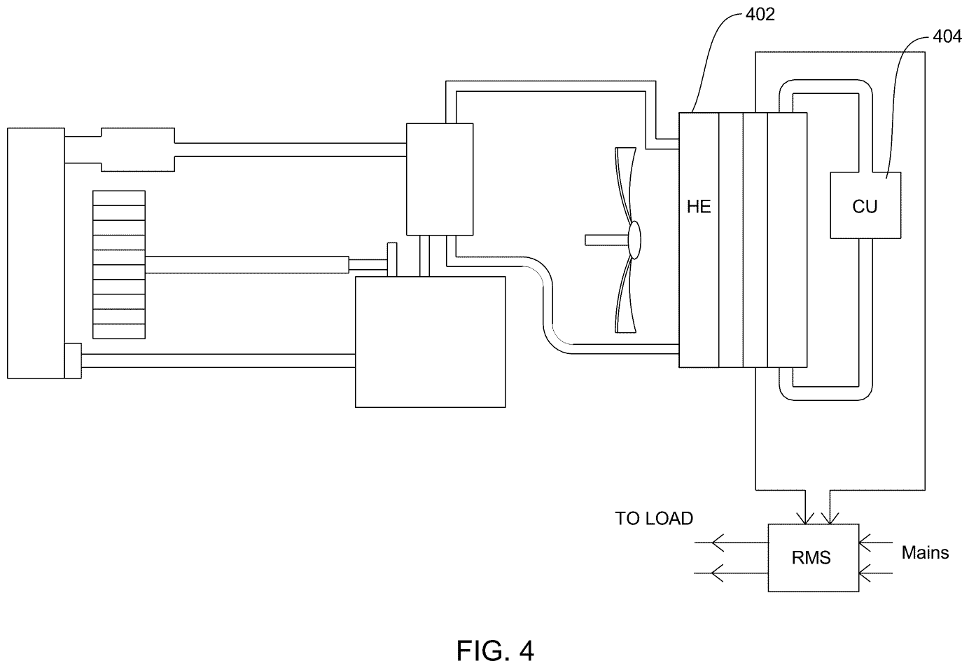

FIG. 4 illustrates a block diagram of internal components of the air conditioner, in accordance with an alternate embodiment of the present invention. In general, an air conditioner is an apparatus for adjusting temperature, humidity, air current, and distribution to optimize conditions for human activities using a cooling cycle, while removing dust, etc. from the air. Main components constituting the cooling cycle include a compressor, a condenser, an evaporator, an expansion valve, and a fan.

The air conditioner can be classified into a split type air conditioner in which an indoor unit is separated from an outdoor unit, and a window type air conditioner in which an indoor unit and an outdoor unit are installed together in a single cabinet. The indoor unit of the split type air conditioner includes an evaporator for cooling air drawn to the inside of an indoor panel, comprising a fan/blower for circulating indoor air through the evaporator comprised in the indoor panel, and again discharging the circulated air to the indoor space.

A typical air-conditioner comprises a heat exchanger thermally coupled to the condenser wherein when the refrigerant is pressurized into a liquid state, heat is generated and carried away by the heat exchanger to be dissipated into the environment. According to an embodiment, the heat exchanger of the air conditioner is replaced by TEG 402. One portion of the TEG 402 may be coupled with the air-conditioner and opposite portion of the TEG 402 may be coupled with coolant unit 404. In order to minimize heat dissipated into the environment, the TEG 402 serves as a heat exchanger and is utilized to first convert the heat captured to electrical energy so that only residual heat is dissipated into the environment.

The electrical energy generated by TEG 402 may be utilized for operating the electronic device 102, specifically the air conditioner. The process of utilization of the auxiliary power may be explained successively in detail using FIG. 3.

As according to an embodiment of the present invention, the TEG (402) is the replacement of the conventional heat exchanger with a Thermoelectric Generator (TEG) denoted as TEG 402. TEGs are solid-state semiconductor devices capable of converting a temperature gradient, or in this context, heat, into electrical energy. In this setup, one part of TEG 402 is linked to the air conditioner, while the opposite part is coupled with a coolant unit 404.

As according to an embodiment of the present invention, the TEG 402 serves a dual purpose. Firstly, it functions as a heat exchanger, taking in the heat generated within the air conditioner, especially during the refrigerant condensation process. Instead of allowing this heat to dissipate into the environment, the TEG captures it for conversion into electrical energy, thus minimizing the wastage of heat energy.

According to an embodiment, the system is configured to capture and convert the heat generated by the electronic device, particularly the air conditioner, into auxiliary power. By leveraging the condensing process and incorporating a thermoelectric device, this system enables the generation of electric power from the abundant waste heat produced by the air conditioner. Consequently, it offers an additional power source for the operation of the air conditioner, enhancing its energy efficiency and sustainability.

As according to an embodiment of the present invention, the electrical energy generated by TEG 402, referred to as auxiliary power, can be employed to operate the electronic device, which, in this context, is the air conditioner itself, wherein the process enhances the air conditioner's energy efficiency and sustainability by using the waste heat produced during its operation to supplement its power needs. As according to the present invention, the integration of TEG technology into the air conditioner system is a significant advancement in optimizing energy usage and reducing environmental impact.

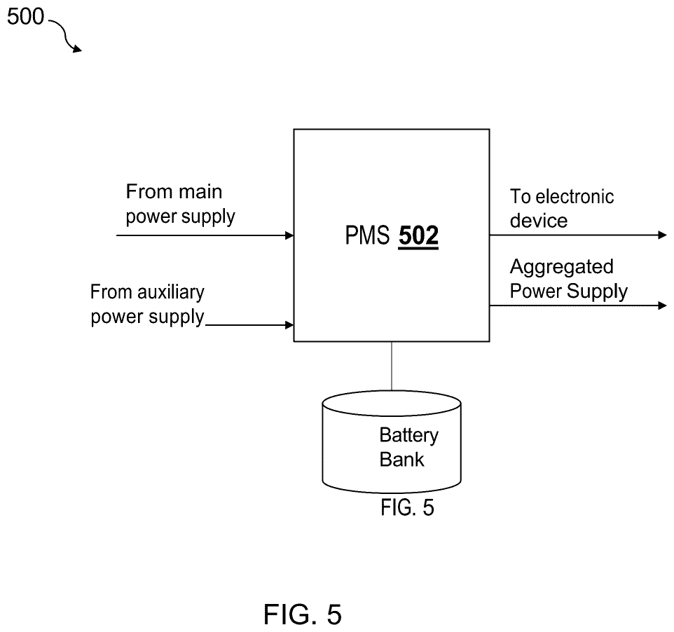

FIG. 5 illustrates a block diagram of a system 500 to harness and utilize auxiliary power effectively, in accordance with an embodiment of the present invention. The system 500 may comprise a Power Management System (PMS) 502 for managing and optimizing input power supply to the electronic device, especially the air conditioner. The PMS 502 may receive power from the primary power supply and the auxiliary power supply and provide aggregated power from the primary and auxiliary power supplies respectively to meet the load requirement of the electronic device. For example, if thermoelectric device generates 80 watts of power, and the load requirement is 1000 watts, then the PMS 502 will draw 920 watts from the primary power supply and aggregate the generated 80 watts of power to meet the requirement of 1000 watts. According to an alternate embodiment, the heat exchanger is replaced entirely by the heat absorbing plate in the thermo-electric generator. Other variations and modifications are possible, likely, and even desirable, as would be apparent to a person having ordinary skill in the art.

The PMS 502 may aggregate the power generated from the heat dissipated by the electronic device and the power from a primary power source and fulfil the load requirement of the electronic device. According to an alternate embodiment, the PMS 502 may store the power from the electric circuit in a connected battery bank to be used as a back-up power source in the event of a power failure.

As According to an embodiment of the present invention, the PMS 502, as mentioned, not only aggregates power from two sources but also serves as a power measurement and aggregator. It measures the load requirement of the electronic device accurately.

According to an embodiment, the PMS 502 may comprise a power measurement and aggregator configured to measure a load requirement. Further, the power measurement and aggregator may aggregate power from the main power supply and the auxiliary power supply based on the measured load requirement, thereby providing the requisite amount of power to the load.

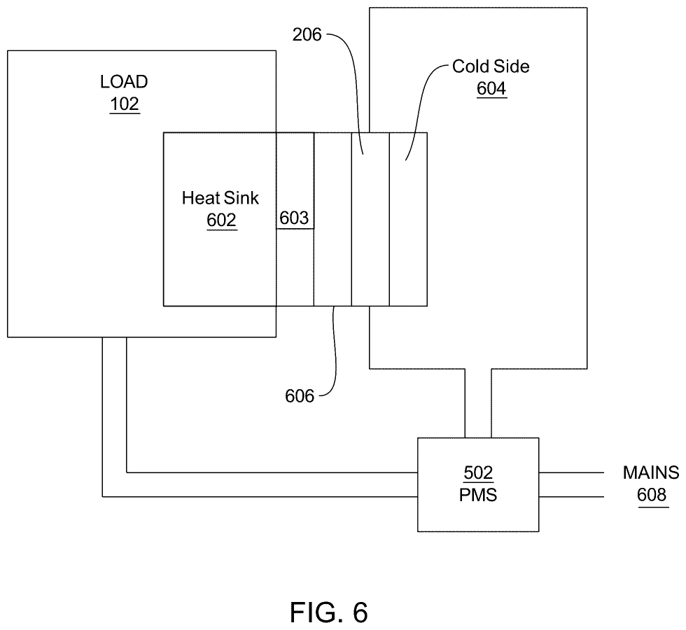

According to another embodiment, the thermoelectric device or TEG 206 may be positioned between a heat generating component of an electrical/electronic device i.e. hot side 602 and a cold side 604, as illustrated in FIG. 6. The hot side 602 represents a portion of the load 102, which is the component of the electronic or electrical device generating heat. A plate 606 may be inserted in close proximity to the thermoelectric device 206 to facilitate effective heat transfer and maintain the required temperature gradient, wherein the plate ensures that the TEG 206 receives a continuous source of heat from the hot side and has a cooler environment on the cold side. The thermoelectric device 206 efficiently converts the captured heat into electrical energy, which is then channelled to the Power Management System (PMS) 502. The PMS 502 may be further connected to the main power supply 608. The PMS 502 may receive power from the primary power supply 608 and the auxiliary power from the thermoelectric device 206. The PMS 502 is configured for aggregating power and supplying the aggregated power to load 102 based on the requirement. For example, if thermoelectric device 206 generates 80 watts of power, and the load 102 has a power requirement of 1000 watts, the PMS 502 will draw 920 watts from the main power supply 608 and aggregate the 80 watts of power generated by the thermoelectric device 206 to meet the total power requirement of 1000 watts. This ensures that the load 102 receives the necessary power supply for its optimal operation.

The above-mentioned embodiment highlights the integration of the thermoelectric device 206 within the overall system. By positioning it between the hot side 602 and the cold side 604, it effectively converts the captured heat into auxiliary power. The PMS 502 plays a crucial role in managing and distributing power, drawing from both the main power supply 608 and the auxiliary power generated by the thermoelectric device 206. This integration and power aggregation process ensures efficient power generation and utilization, optimizing the overall performance of the system.

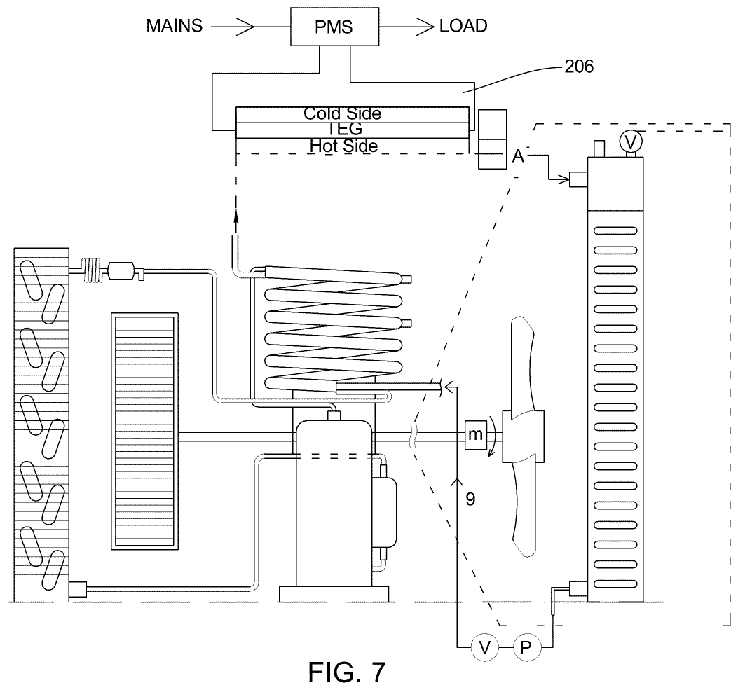

In an alternate embodiment, the hot side of the thermoelectric device or TEG 206 may be coupled with coolant carrying conduit of the air conditioner, as illustrated in FIG. 7. The coolant carrying conduit may absorb heat generated by the condenser. Further, the cold side of the thermoelectric device 206 may be connected to a cold plate. The electrical power generated from the thermoelectric device or TAG 206 may be provided to the PMS 502. The power generated may be considered as the auxiliary power or additional power to be added to the main power received from the main power supply.

As according to an embodiment of the present invention, the hot side of the TAG 206 is configured for transporting and circulating the coolant used in the air conditioning system, wherein the coolant carrying conduit is typically associated with the air conditioner's condenser.

As according to an embodiment of the present invention, the cold side of the TAG 206 helps to maintain the required temperature gradient across the TEG, ensuring effective heat transfer and power generation.

As according to an embodiment of the present invention, the PMS 502 is configured for managing and optimizing the utilization of both the primary and auxiliary power sources to meet the load's power requirements effectively.

As according to another embodiment of the present invention, the TEG 206 is coupled with the air conditioner's coolant carrying conduit, enabling it to capture and convert heat generated by the condenser into auxiliary power and offer an additional power source to enhance energy efficiency, with the PMS 502 coordinating the distribution of power to meet the load's requirements.

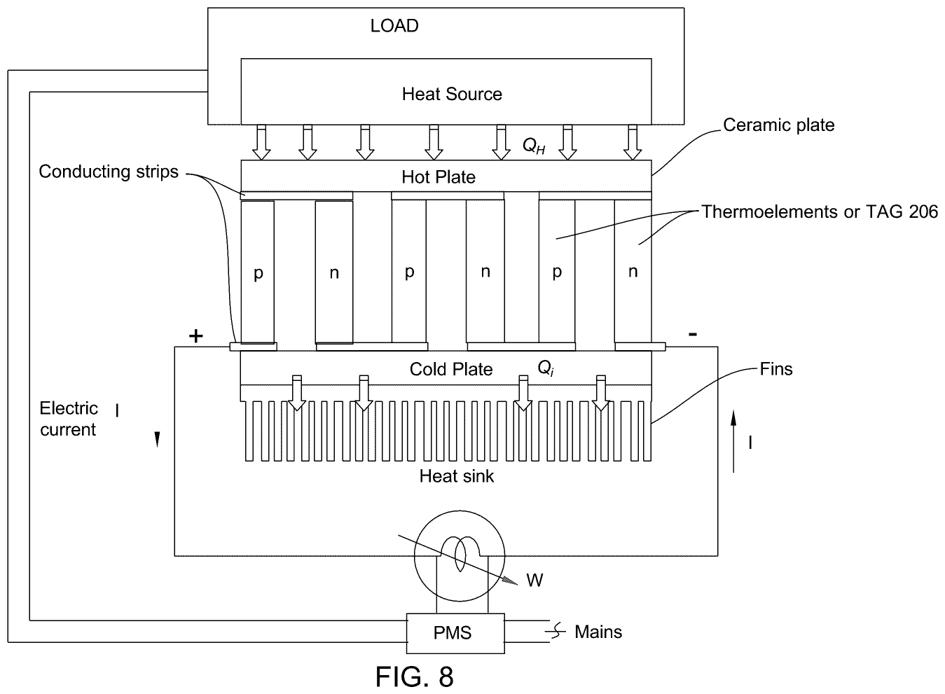

FIG. 8 illustrates a block diagram of the thermoelectric device 206, in accordance with an embodiment of the present invention. The thermoelectric 206 is a solid-state semiconductor device that converts a temperature difference and heat flow into a useful DC power source. The thermoelectric device 206 utilizes the Seebeck effect to generate voltage. This generated voltage drives electrical current and produces useful power at a load.

As illustrated in FIG. 8, the primary heat source is comprised in the load, i.e. the electrical or electronic device. As the load generates heat during operation, the heat energy is transferred to a heat exchanger, such as a hot plate placed in proximity to or in thermal communication with the load. In an embodiment, the hot plate may be a ceramic plate. The hot plate may be connected to the thermo-elements. According to an embodiment, the thermos-elements are made of p-type and n-type semiconductors, wherein one side of the p-type and n-type semiconductors are connected to the hot plate, while the opposite end of the p-type and n-type semi-conductors are connected to a cold plate. The temperature gradient established between the hot plate and cold plate results in a voltage generated within the thermos-elements, i.e. essentially the implementation of Seebeck effect in the thermos-elements, and the voltage drives the flow of electric current. And thus electric power may be generated from the heat recovered. The generated electric power may be provided to the PMS as the auxiliary power source.

As according to the present invention, thermoelectric device 206 plays a crucial role in the present invention, converting the captured heat energy into electrical power. By utilizing the Seebeck effect, the device effectively harnesses the temperature gradient and produces a voltage that drives the flow of electric current. The thermos-elements, along with the hot plate and cold plate arrangement, enable the generation of the auxiliary power that contributes to the overall power supply for the system.

In one embodiment of the present invention, a system for utilizing waste heat from electronic devices for auxiliary power generation is disclosed. The system comprises a thermoelectric device (TEG) integrated into the electronic device, wherein the TEG is positioned between a heat-generating component (hot side) of the electronic device and a cold side. A hot plate, preferably made of ceramic material, is used as a heat exchanger and connected to the hot side of the TEG. The cold side of the TEG is linked to a cold plate. As the electronic device generates heat during operation, the heat energy is transferred to the hot plate, creating a temperature differential across the TEG. This temperature differential enables the TEG to harness the Seebeck effect, generating a voltage and driving electric current. The generated electric power is collected and provided as auxiliary power to a Power Management System (PMS), optimizing the overall power supply for the electronic device.

An example embodiment of the present invention includes an air conditioning system equipped with waste heat recovery capabilities. The system includes an evaporator and a condenser, with the evaporator coils facilitating the conversion of refrigerant from a liquid state to a gaseous state. The expansion valve within the evaporator causes the refrigerant to expand, releasing heat in the process. The gaseous refrigerant is then directed to the compressor via an outlet valve. After compression, the refrigerant enters the condenser, where it undergoes condensation, releasing heat as it returns to a liquid state. To enhance energy efficiency, a TEG is positioned within the system to capture the waste heat generated during these processes. The TEG is placed between the hot components of the system and a cold plate. The electrical power generated by the TEG is fed into a Power Management System (PMS) and used as auxiliary power to support the air-conditioner's operation.

In an alternate embodiment, the system comprises a Power Management System (PMS) 502 that efficiently manages input power supply to electronic devices, specifically air conditioners. The PMS 502 is capable of receiving power from both the primary power supply and an auxiliary power supply generated by thermoelectric devices (TEGs). The TEGs are strategically positioned to capture waste heat from the electronic devices, such as air conditioners, and convert it into electric power. The PMS 502 aggregates power from both sources and ensures that the load requirements of the electronic devices are met. To enhance power reliability, a battery bank is operatively connected between the auxiliary power source and the PMS 502 and ensures continuous power supply even in the event of a primary power source failure.

The present invention includes number of advantages, wherein advantages includes:

Energy Re-utilization: The system and method described allow for the reutilization of heat energy generated by an electronic device, such as an Air Conditioner (AC). By converting the heat energy into electrical energy, the invention enables the generation of auxiliary power that can be used to supplement the power supply of the electronic device. This leads to increased energy efficiency and reduced dissipation of heat into the environment.

Cost Savings: By utilizing the heat energy that would otherwise be wasted, the present invention helps reduce the overall energy consumption of the electronic device from the primary power source. This can result in significant cost savings in terms of electricity bills.

Environmental Benefits: The invention promotes environmental sustainability by harnessing wasted heat energy and converting it into usable electrical power. By reducing energy consumption and dependence on traditional power sources, the present invention contributes to the reduction of greenhouse gas emissions and the overall carbon footprint associated with the operation of electronic devices. More importantly, heat dissipation into the environment is greatly reduced.

Improved Power Management: The Power Management System (PMS) described provides efficient management to the electronic device. By extracting power from both the main power supply and the auxiliary power supply, the PMS ensures a balanced and optimized power distribution based on the load requirement. Additionally, the power management system serves as a voltage regulator. This helps meet the power demands of the electronic device while minimizing power fluctuations and maintaining stable operation.

Backup Power Capability: The incorporation of a battery bank in the system allows for the storage of excess power generated from the auxiliary power supply. In the event of a failure or interruption in the main power supply, the battery bank can supply power to the electronic device via the PMS, ensuring uninterrupted operation and providing a reliable backup power source.

The present invention offers several advantages, including energy reutilization, cost savings, environmental benefits, improved power management, and backup power capability. By harnessing wasted heat energy, the invention promotes energy efficiency and reduces energy consumption. This leads to cost savings and a lower carbon footprint. The PMS ensures optimized power supply and voltage regulation, while the battery bank provides a reliable backup power source. Overall, the present invention provides an efficient and sustainable solution for utilizing heat energy generated by electronic devices.

The figures and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of the embodiments is by no means limited by these specific examples. Numerous variations, whether explicitly given in the specification or not, such as differences in structure, dimension, and use of material, are possible.

We claim:

1. A method for converting heat energy into electrical energy comprising:
via a thermo-electric generator (TEG) comprised in a heat exchanger, converting heat energy into electrical energy based on a temperature differential between a heat concentrator i.e. a hot side, and a heat dissipator, i.e. a cold side comprised in the heat exchanger;
wherein the hot side is operatively coupled to a heat-generating component of an electrical, mechanical, or electro-mechanical device, and the cold side is operatively coupled to the hot side via the thermo-electric generator (TEG);
directing the converted electrical energy to a power management module; aggregating the directed converted electrical energy to the power management module with electrical energy from a primary source; and
based on a monitored load requirement by the power management module, supplying the aggregated power to the electrical, mechanical, or electromechanical device, thereby optimizing heat management and minimizing heat dissipation for the device.

2. The method as claimed in claim 1, wherein the hot side comprises a heat sink comprised in the heat exchanger, and wherein the cold side comprises a heat dissipator comprised in the heat exchanger.

3. The method as claimed in claim 1, wherein the thermo-electric generator (TEG) further comprises a plurality of p-type and n-type semiconductors connected in series to each other.

4. The method as claimed in claim 1, wherein a ratio between the power from the primary source and the power generated by the thermo-electric generator in the aggregated power is based on the load requirement and a quantum of power generated by the thermo-electric generator (TEG).

5. The method as claimed in claim 1, wherein the power management module is further connected to a battery bank for proper operation in case of power failure.

6. A system for converting heat energy to electrical energy, comprising:
a thermo-electric generator (TEG) comprised of a heat exchanger, configured to convert heat energy into electrical energy based on a temperature differential between a heat concentrator, i.e., a hot side, and a heat dissipator, i.e., a cold side comprised in the heat exchanger;
wherein the hot side is operatively coupled to a heat-generating component of an electrical, mechanical, or electro-mechanical device, and the cold side is operatively coupled to the hot side via the thermo-electric generator (TEG);
a power management module configured to:
aggregate the converted electrical energy by the thermo-electric generator (TEG) with electrical energy from a primary source; and
based on a monitored load requirement by the power management module, supply the aggregated power to the electrical, mechanical, or electro-mechanical device, thereby optimizing heat management and minimizing heat dissipation for the device.

7. The system of claim 6, wherein the hot side comprises a heat sink comprised in the heat exchanger, and wherein the cold side comprises a heat dissipator comprised in the heat exchanger.

8. The system of claim 6, wherein the thermo-electric generator (TEG) further comprises a plurality of p-type and n-type semiconductors connected in series to each other.

9. The system of claim 6, wherein a ratio between the power from the primary source and the power generated by the thermo-electric generator in the aggregated power is based on the load requirement and a quantum of power generated by the thermo-electric generator (TEG).

10. The system of claim 6, wherein the electrical, mechanical, or electromechanical device is at least one of an air-conditioner, a battery bank, a compressor, and an internal combustion engine.

11. The system as claimed in claim 10, wherein the air-conditioner comprises a heat sink configured to extract the heat produced by the device through a coolant flowing through a condenser, and wherein the heat sink comprises a hot side coupled with a conduit of the condenser for concentrating the collected heat, a cold side for dissipating the heat, and a thermo-electric generator, operatively coupled to the hot side and the cold side for converting the heat energy into the electrical energy, based on the temperature differential between the hot side and the cold side.

12. The system, as claimed in claim 6, wherein the TEG comprises a heat absorbing plate in thermal communication with the heat exchanger, and wherein the TEG comprises a heat dissipater in thermal communication with a low-temperature environment.

13. The system, as claimed in claim 12, wherein the TEG comprises a plurality of thermoelectric converters present between the heat absorbing plate and the heat dissipater.

14. The system, as claimed in claim 6, wherein the system comprises a battery bank operably connected to the power management module.

15. A system for converting heat energy into electrical energy, comprising: a thermoelectric generator (TEG) comprising a hot side in thermal communication with a heat source in an electrical, mechanical, or electro-mechanical device; a cold side operably coupled to the hot side and distant from the hot side; a plurality of series connected semi-conductor p-n junctions operably connected to the hot side and the cold side; wherein the TEG is configured to convert heat energy into electrical energy based on a temperature differential between the hot side and the cold side to obtain auxiliary power;
a power management module configured to:
aggregate power from a primary power source and the auxiliary power generated by the TEG and at least one of, supply the aggregated power back 10 to the electrical, mechanical, or electro-mechanical device from which the TEG derives auxiliary power, and supply the aggregated power to a power storage or load.

16. The system of claim 13 wherein the heat source is a heat exchanger comprised in an air-conditioning device.
